(19) United States
(12) Patent Application Publication
(10) Pub. No.: US 2026/0338834 A1
(43) Pub. Date: Oct. 29, 2026

(54) TWISTED-PAIR PLASMA CURRENT ROGOWSKI COIL

(71) Applicants: Massachusetts Institute of Technology, Cambridge, MA (US); Commonwealth Fusion Systems LLC, Devens, MA (US)

(72) Inventors: Clayton MYERS, Groton, MA (US); Robert S. Granetz, Newton, MA (US)

(73) Assignees: Massachusetts Institute of Technology, Cambridge, MA (US); Commonwealth Fusion Systems LLC, Devens, MA (US)

(21) Appl. No.: 19/120,588

(22) PCT Filed: Oct. 13, 2023
(86) PCT No.: PCT/US2023/076758

§ 371 Date: Apr. 11, 2025

Related U.S. Application Data
(60) Provisional application No. 63/416,148, filed on Oct. 14, 2022.

(51) Int. Cl. G01R 19/00; G01R 15/18; G21B 1/05

(52) U.S. Cl. CPC G01R 19/0061; G01R 15/181; G21B 1/057

(57) ABSTRACT

A Rogowski-style current sensor includes a twisted pair of wires or cables formed into a coil. A second coil formed from another pair of wires or cables, twisted in the opposite direction, may be placed alongside, but not necessarily immediately adjacent to, the first coil, and the signals from each twisted pair may be added or subtracted to measure the enclosed current or a diamagnetism. When the current to be measured is a plasma current in a tokamak, the current sensor may be placed behind shielding tiles on the inner wall of a vacuum vessel that contains the plasma. Another current sensor may be placed on an external wall of the vacuum vessel, and the outputs subtracted to measure a current flowing through only the vessel itself.

### BACKGROUND

As is known in the art, a tokamak is a device that uses powerful magnetic fields to confine hot plasma in a relatively small volume. In some applications, a tokamak may be used to trigger fusion and the release of substantial amounts of energy. In various tokamaks, the operating plasma may at times reach temperatures of 100 million degrees or even higher.

In this connection, FIG. 1 shows a three-dimensional graphic of a fusion machine 100 (i.e., a tokamak) with a cutaway portion illustrating relevant components. The fusion machine 100 includes a core region 110 for containing plasma, and the cross section of the core region 110 is approximately the shape of the plasma. The core region 110 is surrounded by a neutron shield 120, which also acts as a heat sink and may be provided as a blanket of molten salt (e.g., FLiBe, a mixture of lithium fluoride and beryllium fluoride). The fusion machine 100 also includes a toroidal field magnet coil 130 that is used with many other such coils to magnetically trap the ionized plasma within the core region 110. Separating the plasma in the core region 110 from the neutron shield 120 is a vacuum vessel 140, which physically traps the plasma. The fusion machine 100 has other parts that are not described herein, but are known in the art.

It is useful to sense various physical parameters of a tokamak plasma fusion machine during operation, to ensure maximum efficiency and to prevent abnormal operating conditions, for example. Such parameters may include plasma current within the vacuum vessel, and any asymmetries of the plasma caused by a disruption of the intended magnetic field (e.g., by external magnetic fields or by unexpected behavior of the magnetic coil). Such parameters also may include currents produced in the vacuum vessel by such a disruption. And such parameters may include plasma paramagnetism or diamagnetism, among many others.

Sensors for sensing current and magnetic fields are known in the art of tokamaks. For example, a Rogowski coil 200, as shown in FIG. 2, is an electrical device for measuring current through a target medium 210 as a function of time, i(t), especially alternating current or high-speed current pulses. The coil 200 consists of a helical coil 220 of wire, typically wound around a wire former, with the lead 230 from one end returning through the center of the coil 240 to the other end so that both terminals 230, 250 are at the same end of the coil. The Rogowski coil 200 operates as follows: The helical coil 220 of wire completes a full (or nearly full) poloidal transit to measure the poloidal magnetic field from currents passing through the coil. Typically, the wire doubles back on itself to form a return portion 240 that runs down the middle of the helical coil 220 to cancel contributions from the poloidal loop voltage. Thus, a typical Rogowski coil 200 as known in the art is formed from a single wire, doubled back on itself.

Similarly, a diamagnetic wire loop 300, as shown in FIG. 3, is an electrical device for measuring changes in a magnetic field passing through a medium 310 within a housing 320. Changes in the magnetic field within the wire loop 300 induce a voltage in the wire loop 300 that is measurable.

### SUMMARY OF DISCLOSED EMBODIMENTS

Disclosed embodiments provide a Rogowski-style sensor that may be used to measure current in a medium (e.g., a fusing plasma) having a narrower cross-section than existing Rogowski coils. Prior art Rogowski coils used a single wire having a helical portion wound around a former, which portion therefore has a diameter at least as large as the former. By contrast, disclosed embodiments may include two wires in a twisted pair, which may have a cross-section diameter of only twice that of the wire. This configuration allows the sensor to fit into a space having a diameter smaller by one-third than in the prior art, which facilitates use in a space-constrained environment.

In some aspects, the techniques described herein relate to a current sensor, including: a first Rogowski coil including at least one first conductor and at least one second conductor twisted in a first twist direction; and a second Rogowski coil including a least one third conductor and at least one fourth conductor twisted in a second twist direction.

In some aspects, the techniques described herein relate to a current sensor, wherein the at least one first conductor has a width of no more than 2 millimeters.

In some aspects, the techniques described herein relate to a current sensor, wherein the first Rogowski coil runs alongside the second Rogowski coil.

In some aspects, the techniques described herein relate to a current sensor, further including circuitry configured to determine a sum of a first signal from the first Rogowski coil and a second signal from the second Rogowski coil.

In some aspects, the techniques described herein relate to a current sensor, further including circuitry configured to determine a difference between a first signal from the first Rogowski coil and a second signal from the second Rogowski coil.

In some aspects, the techniques described herein relate to a current sensor, wherein the current sensor is configured to measure a plasma current of a tokamak fusion machine.

In some aspects, the techniques described herein relate to a current sensor, wherein the current sensor is configured to be disposed in a channel of a vacuum vessel of a tokamak plasma fusion machine.

In some aspects, the techniques described herein relate to a current sensor, wherein the first Rogowski coil is a first twisted-pair Rogowski coil and the second Rogowski coil is a second twisted-pair Rogowski coil.

In some aspects, the techniques described herein relate to an apparatus, including: a vacuum vessel having at least one channel in an exterior of the vacuum vessel; a current sensor disposed in the at least one channel.

In some aspects, the techniques described herein relate to an apparatus, wherein the apparatus includes a plasma fusion machine.

In some aspects, the techniques described herein relate to an apparatus or claim 10, wherein the current sensor includes at least one Rogowski coil.

In some aspects, the techniques described herein relate to an apparatus, wherein the at least one Rogowski coil includes a twisted-pair Rogowski coil or a Rogowski coil with a center conductor.

In some aspects, the techniques described herein relate to an apparatus, wherein the at least one channel has a depth of no more than 5 mm.

In some aspects, the techniques described herein relate to a current sensor, including: a first coil including at least one first conductor and at least one second conductor twisted in a first twist direction; and a second coil including a least one third conductor and at least one fourth conductor twisted in a second twist direction.

In some aspects, the techniques described herein relate to a method of measuring an electromagnetic parameter, including: processing signals from: a first coil including at least one first conductor and at least one second conductor twisted in a first twist direction; and a second coil including a least one third conductor and at least one fourth conductor twisted in a second twist direction.

In some aspects, the techniques described herein relate to a method, wherein the measuring includes subtracting a signal from the first coil from a signal from the second coil and the electromagnetic parameter includes a current.

In some aspects, the techniques described herein relate to a method, wherein the measuring includes adding a signal from the first coil to a signal form the second coil and the electromagnetic parameter includes diamagnetic flux.

In some aspects, the techniques described herein relate to an apparatus, including: a neutron and/or thermal shield including shielding tiles, wherein at least one channel is formed between adjacent shielding tiles; and at least one twisted pair within the at least one channel.

In some aspects, the techniques described herein relate to an apparatus, further including at least one second twisted pair within the at least one channel.

In some aspects, the techniques described herein relate to a method of forming an apparatus, including placing at least one twisted pair between respective regions of a neutron and/or thermal shield.

The foregoing summary is provided by way of illustration and is not intended to limit the scope of the claims.

### DESCRIPTION OF THE SEVERAL VIEWS OF THE DRAWINGS

The manner and process of making and using the disclosed embodiments may be appreciated by reference to the drawings, in which:

FIG. 1 schematically shows a three-dimensional graphic of a fusion machine known in the art, in which may be used embodiments of the concepts, techniques, and structures disclosed herein;

FIG. 2 schematically shows a single-wire Rogowski coil current sensor as known in the art;

FIG. 3 schematically shows a single-wire diamagnetic loop magnetic field sensor as known in the art;

FIG. 4 schematically shows a portion of a vacuum vessel of a fusion machine indicating design constraints for an internal current sensor;

FIG. 5 shows two twisted-pair Rogowski-style sensors in accordance with embodiments of the concepts, techniques, and structures disclosed herein;

FIG. 6 schematically shows a cross section of a vacuum vessel of a fusion machine indicating design constraints for an external current sensor;

FIGS. 7A-7C (collectively “Fig. 7”) are plots of current and sensed signal within a test apparatus having a Rogowski-style sensor that does not enclose the current, in accordance with disclosed embodiments, in which FIG. 7A relates to a single twisted-pair sensor, and FIGS. 7B and 7C relate to a double-twisted-pairs sensor; and

FIGS. 8A-8B (collectively “FIG. 8”) are plots of current and sensed signal within a test apparatus having a Rogowski-style sensor that encloses the current, in accordance with disclosed embodiments, in which FIG. 8A relates to a single twisted-pair sensor, and FIG. 8B relates to a double-twisted-pairs sensor.

FIG. 9 shows an example of circuitry for processing signals from the twisted pairs.

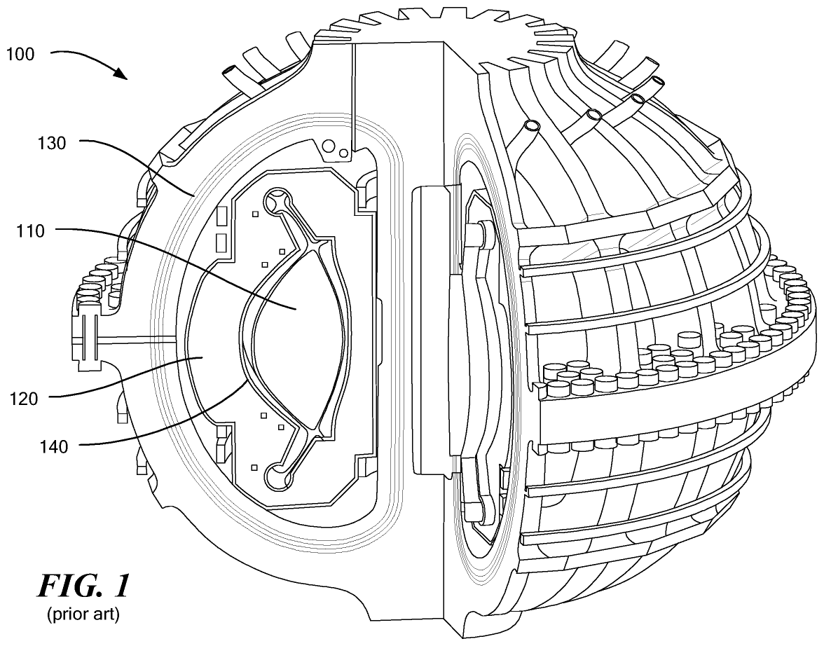

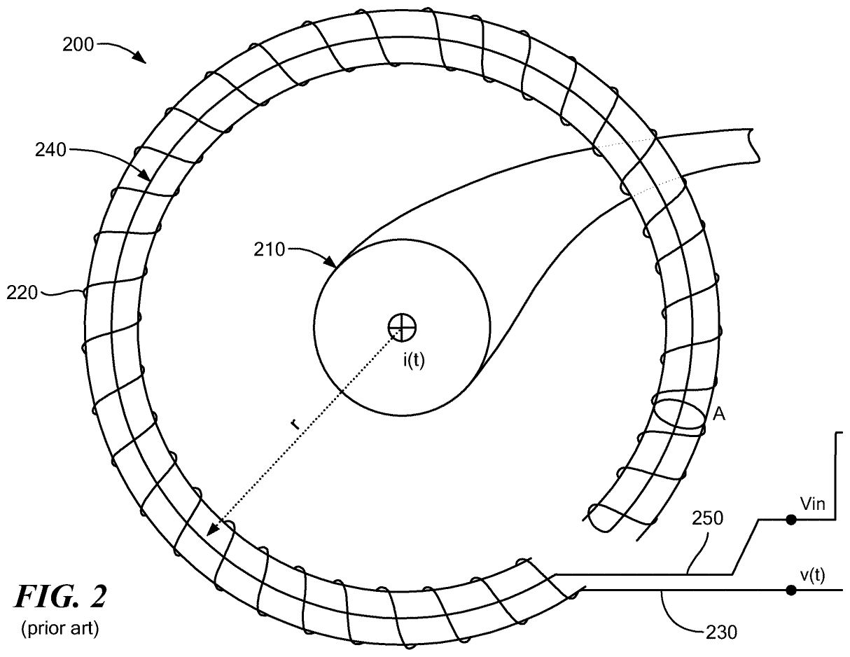

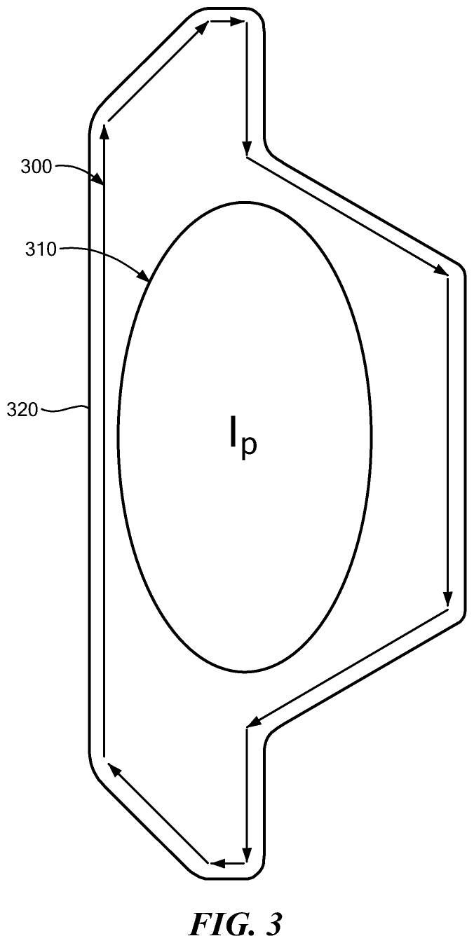

### DETAILED DESCRIPTION OF EMBODIMENTS

Embodiments of the concepts, techniques, and structures disclosed herein may be advantageously used to sense electrical current flowing in a medium. In what follows, the medium is taken to be a hot plasma optionally undergoing fusion for purposes of illustration, but embodiments are not limited to that use.

In tokamaks, neutrally charged matter (typically hydrogen atoms) is heated to great temperatures, causing ionization. The now-ionized plasma is trapped within a torus using powerful magnetic fields supplied by toroidal field electromagnets. Applying a toroidal electric field produces a powerful electrical current within the ionized plasma, which adds a poloidal magnetic field to the aforementioned toroidal magnetic field. Illustratively, and without limitation, this plasma current may be between 0.1 megaamperes (MA) and 9.0 MA and may vary within about ±10 kiloamperes (kA). These magnetic fields may generate current within any nearby electrically conductive object, such as the vacuum vessel that confines the plasma.

To optimize operation of the tokamak, and to prevent unexpected deviations from normal operation, its physical parameters may be measured using sensors. A current sensor may be placed on the interior surface of the vacuum vessel to measure the plasma current alone. Another current sensor may be placed on the exterior surface of the vacuum vessel to measure the sum of the plasma current and any current that is flowing through the vacuum vessel. And a magnetic flux sensor may be placed on the interior surface of the vacuum vessel to measure the plasma-generated toroidal magnetic flux mentioned above.

As fusion machines become smaller, their electronics are necessarily placed closer to the fusing plasma and are thus exposed to greater radiation and temperatures. In environments where space is not at a premium, one would compensate for these material challenges by using larger-diameter wires for electrical components (including sensors). However, this approach may be precluded when shrinking size is the overriding design goal. In such situations, previously known Rogowski coils for measuring current are too large and cannot be used.

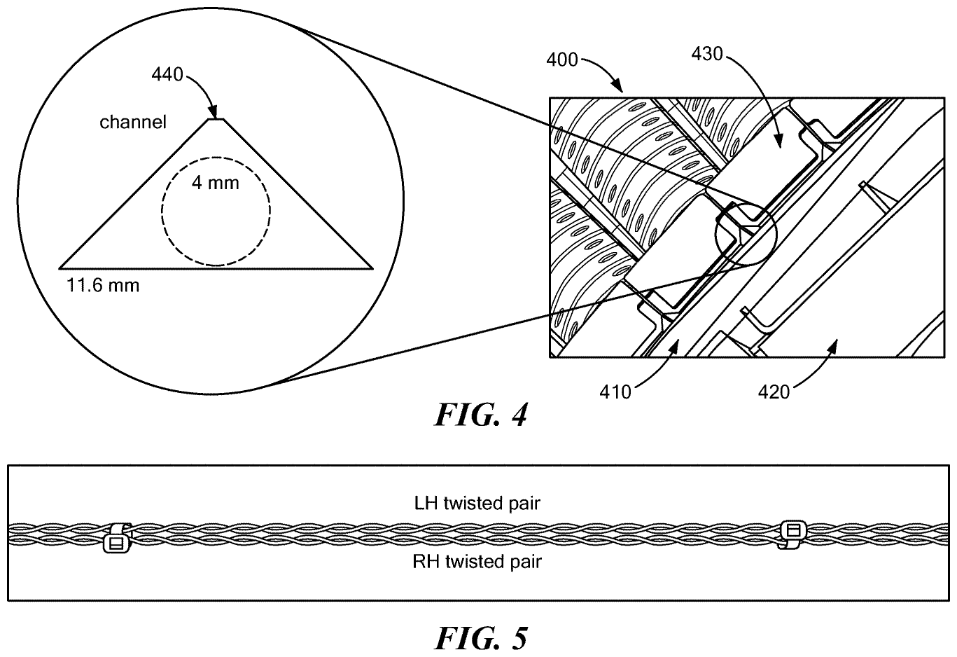

In this connection, FIG. 4 schematically shows a portion of a vacuum vessel of a fusion machine indicating design constraints for an internal current sensor. The vacuum vessel itself may be manufactured using materials and techniques known in the art of tokamaks, for example. The interior of the vacuum vessel, i.e., the reaction chamber confining the fusing plasma, is indicated by the numeral 400. The vacuum vessel itself has an interior surface 410 and an exterior surface 420. A series of shielding tiles, of which tile 430 is one, lines the interior surface 410 and shields it from direct contact with the plasma and from radiation and high temperatures. The shielding tiles 430 may be made of tungsten or any other suitable material.

A sensor meant to sense current only from the plasma and not from the vacuum vessel may be placed inside the vessel body itself. On the other hand, the sensor should not be exposed directly to the fusing plasma on the interior surface, or it will rapidly suffer material failure. Therefore, such a sensor has a limited space in which it may be located. To this end, chamfered channels, such as channel 440, may be made in the shielding tiles to accommodate sensor wires. In relation to an illustrative embodiment, these channels may be made only large enough to accommodate sensor wires having a total diameter of 4 mm, as indicated. But due to the high-radiation environment, a thick wire (e.g., a 2 mm diameter mineral-insulated cable) may be needed. Fashioning this wire into a prior art Rogowski coil would require a former diameter of at least 10 mm to accommodate the bend radius of the cable, and doing so would produce a coil that is far too large to fit into the available space. An alternate sensor arrangement was therefore developed.

FIG. 5 shows two twisted-pair Rogowski-style sensors in accordance with embodiments of the concepts, techniques, and structures disclosed herein. In the prior art Rogowski sensor, a single wire (or cable) was helically wrapped around a former, the former was removed, and the wire was doubled back through the helix without twisting. By contrast, in accordance with embodiments, two wires are helically wrapped around each other to form a twisted pair. In FIG. 5 is shown two such twisted pairs, one twisted in a left-handed fashion and the other is disposed alongside in a right-handed fashion. Each wire illustratively has a diameter of 2 mm, so each twisted pair forms a coil having a diameter of 4 mm—small enough to fit into the channel 440. It is appreciated that the channel 440 may have other sizes, and therefore the diameter of 2 mm is illustrative only, as larger or smaller diameter wires may be used so long as their twisted pairs fit within the corresponding channel.

An electrical joint may be used to connect the wires of one or more twisted pair. In accordance with embodiments, the wires may be joined outside the vacuum vessel to simplify sensor maintenance. Each twisted pair may have four leads: one lead on each of the two ends, on each of the two wires. The double twisted pair configuration shown in FIG. 5 thus will have eight leads. As noted, pairs of these leads may be coupled outside the vacuum vessel to form a single electrical path. In various embodiments, the remaining leads may be coupled to a circuit for producing measurement data (e.g., representative of the plasma current) based on the current sensed in the twisted pair(s). This circuit may be an analog circuit containing operational amplifiers and other components for performing analog signal processing. It is appreciated that digital circuitry for such computations may be adversely impacted by close proximity to neutron radiation generated by the fusing plasma.

These two twisted pairs may be twisted in opposite directions, as shown. Moreover, subtracting signals from side-by-side twisted pairs provides a measurement of the plasma current, while adding their signals provides a measurement of the plasma diamagnetism. The channel 440 shown in FIG. 4 does not have enough room to fit two twisted pairs side-by-side, however simulation indicates that placing oppositely twisted pairs in adjacent channels provides sufficient sensor accuracy. In other words, a first twisted pair may be placed in a first channel in the shielding tiles, and a second twisted pair may be placed in a second channel in the shielding tiles. The first channel may be adjacent to the second channel. For example, the first channel may be between first and second shielding tiles, and the second channel may be between the second shielding tile and a third shielding tile.

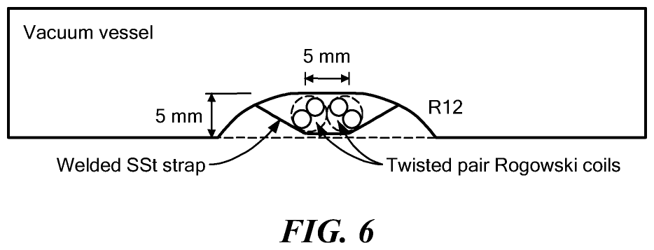

FIG. 6 schematically shows a cross section of a vacuum vessel of a fusion machine indicating design constraints for an external current sensor. As noted above, it may be desired to provide a sensor for sensing a total current within the plasma and within the vacuum vessel. By subtracting the current sensed within the plasma alone (e.g., using an internal sensor as described above), the remaining current is that current flowing only through the vacuum vessel itself. Such a second sensor may be placed on an exterior surface of the vacuum vessel, as shown. A trench may be cut into the exterior surface of the vessel, into which may be placed two side-by-side twisted pairs of wires. The twisted pairs may themselves be secured to the exterior surface of the vacuum vessel using a welded strap or other suitable means.

Both the inside-and outside-vessel constraints may require that the cross-section of each twisted pair be limited to 4 mm. It is now shown that a single twisted-pair sensor as described above is sufficiently sensitive to permit meaningful measurement of the plasma current in an illustrative embodiment.

Suppose each wire in the twisted pair is a 2 mm diameter mineral-insulated cable. Given integrator gain limitations (τ_{RC}≥1 ms), the minimum viable sensor flux generated by 8.7 MA of current may be Φ≥1 milliweber (mWb). Now consider that the flux in a Rogowski coil is given by Φ=NA<B> where: (a) the number of turns over an 8.2 m poloidal transit at 20 mm helical pitch is N=410; (b) the sensing area for a helically-twisted wire having twist radius of 2 mm is A=12.57 mm²; and (c) the average field at the vessel wall is illustratively <B>=1.3 T. The resulting flux for a single wire in a twisted-pair Rogowski-style coil in accordance with embodiments is Φ=6.7 mWb—safely more than the example minimum described above. It is appreciated that the design parameters just recited are not limiting, and that other designs may use other parameters. It is further appreciated that, while the twisted pairs shown in FIG. 6 run alongside each other, the wires may themselves be retained within a sheath or other cable housing to prevent direct contact between the wires and the strap that retains the cables in the trench, as shown.

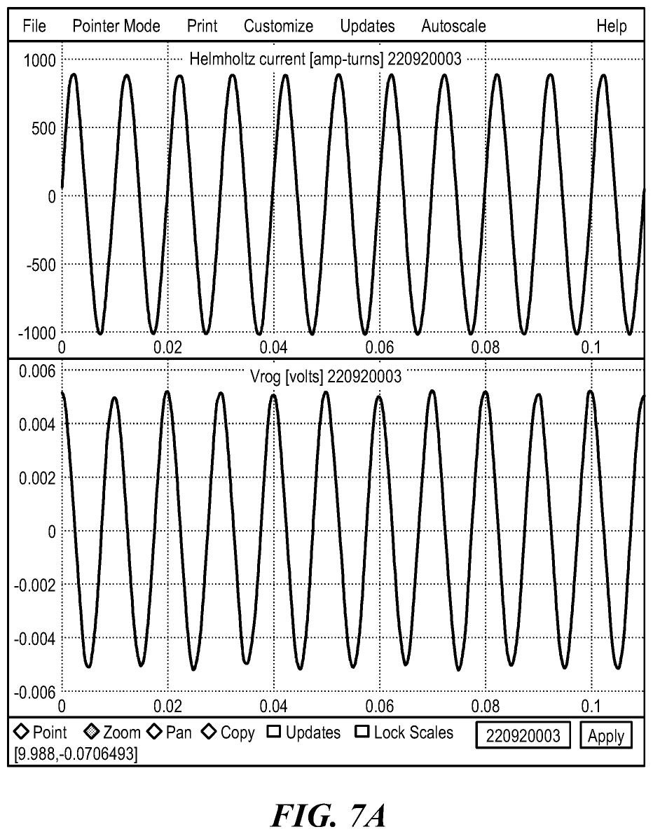

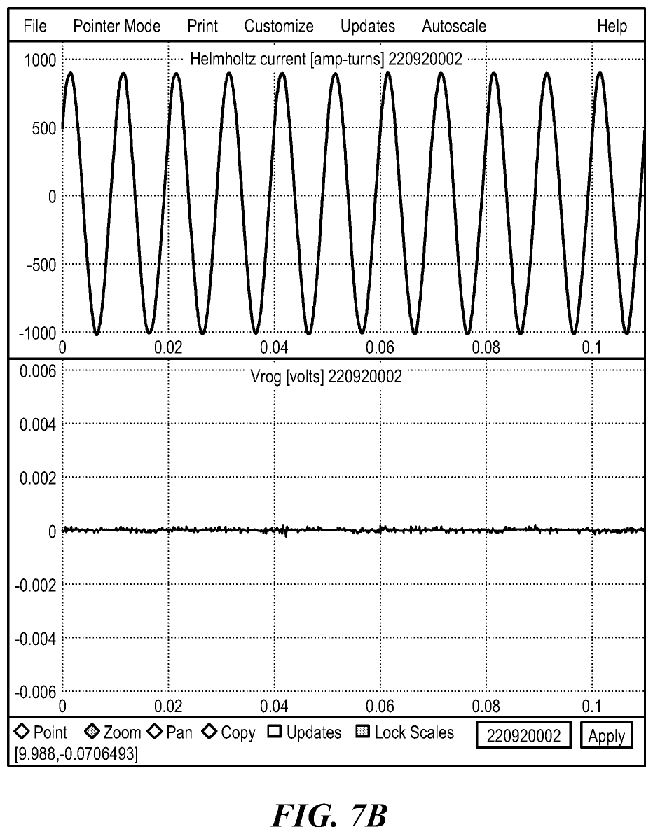

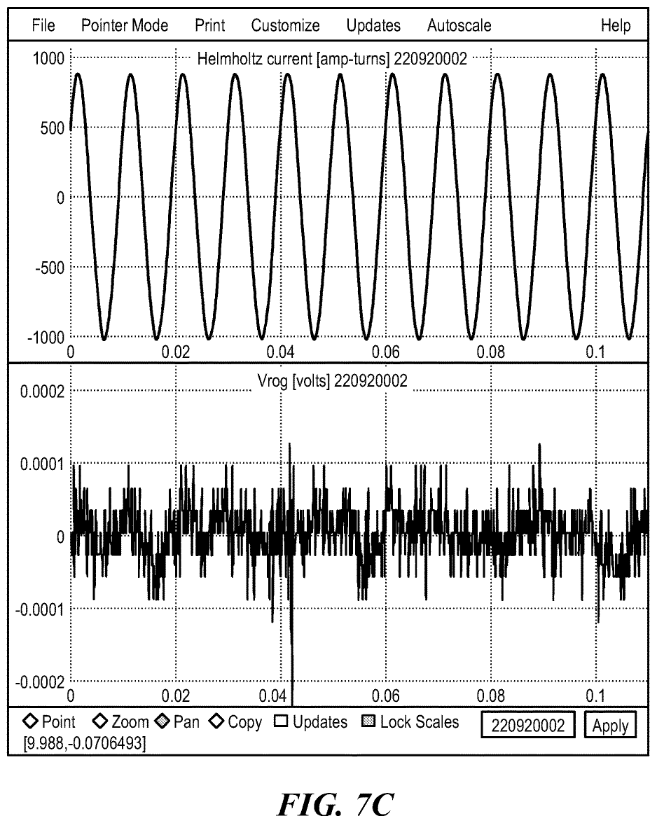

FIGS. 7A-7C (collectively “FIG. 7”) are plots of current and sensed signal within a test apparatus having a Rogowski-style sensor that does not enclose the current, in accordance with disclosed embodiments. FIG. 7A relates to a single twisted-pair sensor, and FIGS. 7B and 7C relate to a double-twisted-pairs sensor. Each Figure has an upper panel that indicates current as a function of time, and a lower panel that indicates a corresponding measured output voltage in the Rogowski-style sensor.

FIG. 7A shows that, when a regular alternating current is provided, the latter provides a regularly oscillating magnetic field that is detected by the single twisted-pair Rogowski-style sensor. Note the sensitivity that may be needed; a peak-to-peak (simulated plasma) current of about 1900 amp-turns corresponds to a peak-to-peak sensor voltage of about 10 mV.

FIG. 7B shows the same current, but detected by two twisted pairs (e.g., as shown in FIG. 5) whose outputs are subtracted. The output difference signal is essentially zero.

FIG. 7C shows the same input and output signals, but with the output signal zoomed in by a factor of roughly 30× to provide more detail. It may be seen from FIG. 7C that the output of the double twisted-pair sensor consists almost entirely of analog-to-digital noise.

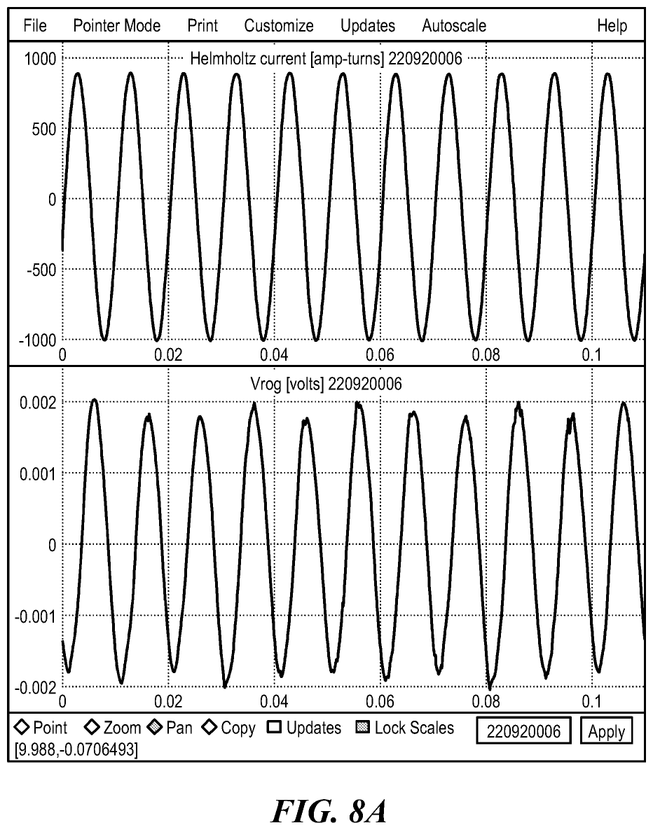

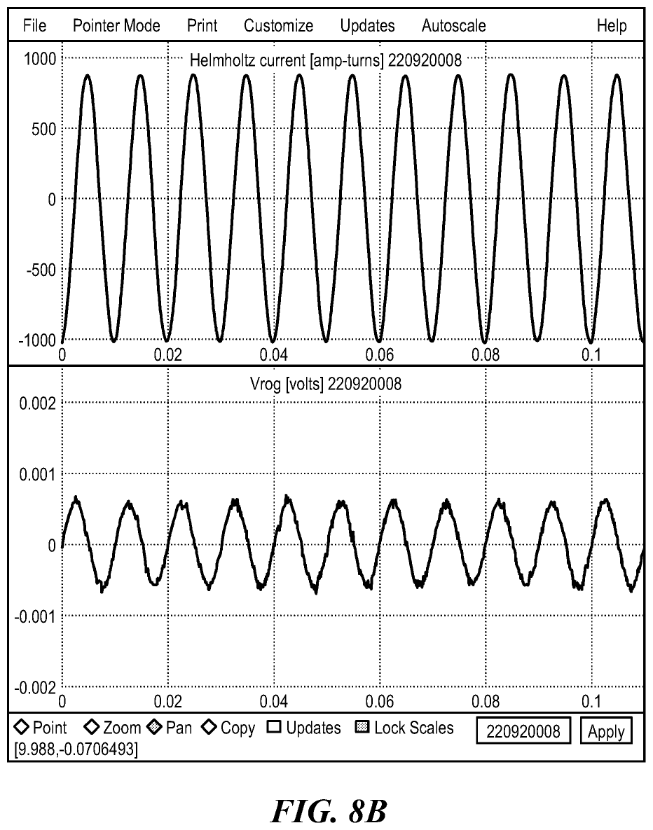

FIGS. 8A-8B (collectively “FIG. 8”) are plots of current and sensed signal within a test apparatus having a Rogowski-style sensor that encloses the current, in accordance with disclosed embodiments. FIG. 8A relates to a single twisted-pair sensor, and FIG. 8B relates to a double-twisted-pairs sensor. FIG. 8B illustrates the sensitivity of the Rogowski-style sensor disclosed herein.

When a single twisted-pair sensor loop enclosed the current, it detected the regularly oscillating magnetic field, as shown in FIG. 8A. However, the output signal was significantly stronger than expected, and included a 60 Hz tone (presumably from unshielded electrical mains within the testing room). However, when a double twisted-pair sensor loop (e.g., as shown in FIG. 5) enclosed the current, and its signals subtracted, as shown in FIG. 8B, the output difference signal was close to the expected detection strength and the 60 Hz tone disappeared. Thus, the inventors demonstrated that the double twisted-pair embodiment was able to accurately measure the current, while eliminating or at least significantly reducing sensitivity to unwanted external magnetic fields.

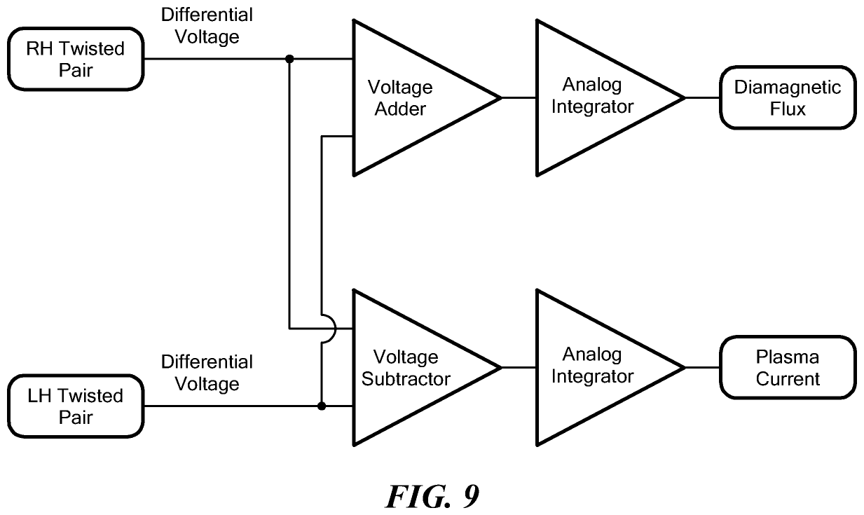

FIG. 9 shows an example of circuitry that may be used to process the signals from the twisted pairs. As mentioned above, signals from the RH twisted pair and LH twisted pair may be used to determine the diamagnetic flux and/or the plasma current. In FIG. 9, the label “Differential Voltage” refers to a signal representing the difference between the voltages across the two wires of a twisted pair. The differential voltages of the RH twisted pair and the LH twisted pair may be summed and integrated to determine the diamagnetic flux. The differential voltages of the LH twisted pair may be subtracted and integrated to determine the plasma current. In some embodiments, such as those in which components may operate in an environment with a high level of ionizing radiation, the circuitry for processing the signals from the twisted pairs may be analog circuitry, which may be less sensitive to radiation. In other embodiments, such as those without elevated levels of ionizing radiation, the signals may be processed at least partially using digital circuity, as the techniques and apparatus described herein are not limited to the particular type of circuitry used to process the signals. In some embodiments, circuitry for adding and/or subtracting voltage signals may include a series connection of voltage signals in the corresponding polarity.

It is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter.

In the foregoing detailed description, various features of embodiments are grouped together in one or more individual embodiments for the purpose of streamlining the disclosure. This method of disclosure is not to be interpreted as reflecting an intention that the claims require more features than are expressly recited therein. Rather, inventive aspects may lie in less than all features of each disclosed embodiment.

Although the disclosed subject matter has been described and illustrated, it is understood that the present disclosure has been made only by way of example, and that numerous changes in the details of implementation of the disclosed subject matter may be made without departing from the spirit and scope of the disclosed subject matter.

As used herein, “including” means including without limitation. As used herein, the terms “a” and “an”, when modifying a noun, do not imply that only one of the nouns exists. As used herein, unless the context clearly indicates otherwise, “or” means and/or.

For example, A or B is true if A is true, or B is true, or both A and B are true. As used herein, “for example”, “for instance”, “e.g.,”, and “such as” refer to non-limiting examples that are not exclusive examples. The word “consists” (and variants thereof) are to be given the same meaning as the word “comprises” or “includes” (or variants thereof).

Various embodiments of the concepts, systems, devices, structures, and techniques sought to be protected are described herein with reference to the related drawings.

Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection.”

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. For purposes of the description herein, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements. The term “alongside” as applied to two elements relates to those elements extending together in a direction and does not necessarily mean “touching” or “immediately next to” as there may be intervening elements.

Use of ordinal terms such as “first,” “second,” “third,” etc., in the specification to modify an element does not by itself connote any priority, precedence, or order of one element over another or the temporal order in which acts of a method are performed, but are used merely as labels to distinguish one element having a certain name from another element having a same name (but for use of the ordinal term) to distinguish the elements. The terms “approximately” and “about” may be used to mean within +20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within +2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

1. A current sensor, comprising:
a first coil comprising at least one first conductor and at least one second conductor twisted in a first twist direction; and
a second ki-coil comprising at least one third conductor and at least one fourth conductor twisted in a second twist direction.

2. The current sensor of claim 1, wherein the first and second coils each comprise a Rogowski coil.

3. The current sensor of claim 2, wherein the first Rogowski coil runs alongside the second Rogowski coil.

4. The current sensor of claim 2, further comprising circuitry configured to determine a sum of a first signal from the first Rogowski coil and a second signal from the second Rogowski coil.

5. The current sensor of claim 2, further comprising circuitry configured to determine a difference between a first signal from the first Rogowski coil and a second signal from the second Rogowski coil.

6. The current sensor of claim 1, wherein the current sensor is configured to measure a plasma current of a tokamak fusion machine.

7. The current sensor of claim 1, wherein the current sensor is configured to be disposed in a channel of a vacuum vessel of a tokamak plasma fusion machine.

8. The current sensor of claim 2, wherein the first Rogowski coil is a first twisted-pair Rogowski coil and the second Rogowski coil is a second twisted-pair Rogowski coil.

9. An apparatus, comprising:
a vacuum vessel having at least one channel in an exterior of the vacuum vessel; wherein a current sensor is disposed in the at least one channel.

10. The apparatus of claim 9, wherein the apparatus comprises a plasma fusion reactor.

11. The apparatus of claim 9 wherein the current sensor comprises at least one Rogowski coil.

12. The apparatus of claim 11, wherein the at least one Rogowski coil comprise a twisted-pair Rogowski coil or a Rogowski coil with a center conductor.

13. The apparatus of claim 9, wherein the at least one channel has a depth of no more than 5 mm.

14. (canceled)

15. A method of measuring an electromagnetic parameter, the method comprising:
processing signals from both of:
a first coil comprising at least one first conductor and at least one second conductor twisted in a first twist direction; and
a second coil comprising at least one third conductor and at least one fourth conductor twisted in a second twist direction.

16. The method of claim 15, wherein the measuring comprises subtracting a signal from the first coil from a signal from the second coil and the electromagnetic parameter comprises a current.

17. The method of claim 15, wherein the measuring comprises adding a signal from the first coil to a signal form the second coil and the electromagnetic parameter comprises diamagnetic flux.

18. The apparatus of claim 9, wherein the exterior of the vacuum vessel has a neutron shield or a thermal shield, the neutron shield or thermal shield comprising shielding tiles, wherein the at least one channel is formed between adjacent shielding tiles; and wherein the current se or comprises at least one twisted pair disposed within the at least one channel.

19. The apparatus of claim 18, further comprising at least one second twisted pair within the at least one channel.

20. (canceled)

21. The current sensor of claim 1, wherein the at least one first conductor has a width of no more than 2 millimeters.
